(19) United States
(12) Patent Application Publication
(10) Pub. No.: US 2026/0126723 A1
(43) Pub. Date: May 7, 2026

(54) SEMICONDUCTOR PHOTORESIST COMPOSITION AND METHOD OF FORMING PATTERNS USING THE COMPOSITION

(71) Applicant: Samsung SDI Co., Ltd., Yongin-si (KR)

(72) Inventors: Kyoungah OH, Suwon-si (KR); Seung-Wook SHIN, Suwon-si (KR); Minhye KIM, Suwon-si (KR); Jihyun YOON, Suwon-si (KR); Eunmi KANG, Suwon-si (KR); Jimin KIM, Suwon-si (KR)

(21) Appl. No.: 19/374,966

(22) Filed: Oct. 30, 2025

(30) Foreign Application Priority Data
Nov. 1, 2024 (KR) 10-2024-0153667

(51) Int. Cl. G03F 7/004; G03F 7/00; H01L 21/027; H01L 21/311; H01L 21/3213; H01L 21/67

(52) U.S. Cl. CPC G03F 7/0042; G03F 7/0045; G03F 7/70025; G03F 7/70033; H10P 50/71; H10P 50/73; H10P 72/0421; H10P 76/2042

(57) ABSTRACT

A semiconductor photoresist composition and a method of forming patterns using the semiconductor photoresist composition are provided. The semiconductor photoresist composition including an organometallic compound, a carboxylic acid compound represented by Chemical Formula 1; and a solvent.

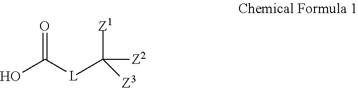

### CROSS-REFERENCE TO RELATED APPLICATION

The present application claims priority to and the benefit of Korean Patent Application No. 10-2024-0153667, filed on Nov. 1, 2024, in the Korean Intellectual Property Office, the entire content of which is incorporated herein by reference.

### BACKGROUND

### 1. Field

One or more embodiments of the present disclosure relate to a semiconductor photoresist composition and a method of forming patterns using the same.

### 2. Description of the Related Art

Extreme ultraviolet (EUV) lithography has emerged as an important technology for manufacturing next-generation semiconductor devices, such as advanced semiconductor chips (e.g., next generation semiconductor chips). EUV lithography utilizes EUV radiation with a wavelength of 13.5 nm as an exposure light source, enabling the formation of extremely fine patterns, for example, patterns having critical dimensions of 20 nm or less.

Achieving high-resolution patterning with EUV lithography requires the development of compatible photoresists capable of sub-16 nm resolution. However, chemically amplified (CA) photoresists currently face limitations in resolution, photospeed, and line edge roughness (LER), which hinder their performance in advanced lithographic processes.

In CA photoresists, acid-catalyzed reactions may cause image blurring, particularly at small feature sizes, a limitation also observed in electron beam lithography. Although CA photoresists are designed for high sensitivity, their typical elemental composition results in low absorbance at 13.5 nm, thereby reducing sensitivity under EUV exposure.

Additionally, CA photoresists often exhibit increased LER as photospeed decreases, due in part to the stochastic nature of acid diffusion and reaction. These limitations create the need or desire for novel, high-performance photoresist materials suitable for EUV lithography.

In response, research has turned to inorganic photoresist compositions, which are primarily used for negative tone patterning. These compositions undergo chemical modification through non-chemically amplified mechanisms, providing resistance to developer solutions. Inorganic photoresists typically contain elements with higher EUV absorption than hydrocarbons, offering improved sensitivity, reduced stochastic effects, and lower LER.

Inorganic photoresists based on peroxopolyacids of tungsten, optionally mixed with elements such as niobium, titanium, and/or tantalum, have been explored as radiation sensitive materials for patterning.

These materials have demonstrated efficacy in patterning large-pitch features using bilayer configurations and various radiation sources, including deep UV, X-ray, and electron beam. For example, cationic hafnium metal oxide sulfate (HfSOx) materials, when combined with a peroxo complexing agent, have enabled imaging of 15 nm half-pitch features via EUV projection exposure. While this system offers high performance and acceptable photospeed, it suffers from practical drawbacks: (i) the coating process involves corrosive sulfuric acid/hydrogen peroxide mixtures, leading to poor shelf-life stability; (ii) structural modifications for performance enhancement are difficult; and (iii) development requires highly concentrated tetramethylammonium hydroxide (TMAH) solutions (e.g., 25 wt %).

To address these issues and challenges, recent efforts have focused on tin-containing molecules with strong EUV absorption. Among these, organotin polymers have shown promise. Upon EUV exposure, alkyl ligands dissociate and form oxo bonds with adjacent chains, enabling negative tone patterning resistant to organic developers. Although these organotin polymers exhibit improved sensitivity, resolution, and LER, further enhancements are needed or desired to meet commercial performance requirements.

### SUMMARY

One or more aspects of embodiments of the present disclosure are directed toward a semiconductor photoresist composition that has excellent or suitable resolution characteristics and pattern adhesive force by reducing the influence of variables during pattern formation and thus improves CD (critical dimension) stability.

One or more aspects of embodiments of the present disclosure are directed toward a method of forming patterns using the semiconductor photoresist composition.

Additional aspects will be set forth in part in the description which follows and, in part, will be apparent from the description, or may be learned by practice of the presented embodiments of the disclosure.

According to one or more embodiments of the present disclosure, a semiconductor photoresist composition includes an organometallic compound, a carboxylic acid compound represented by Chemical Formula 1, and a solvent:

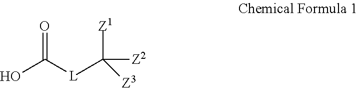

In Chemical Formula 1, L may be a single bond, a substituted or unsubstituted C1 to C10 alkylene group, a substituted or unsubstituted C2 to C10 alkenylene group, or a substituted or unsubstituted C2 to C10 alkynylene group, and Z¹ to Z³ may each independently be hydrogen, a hydroxyl group, a halogen, a cyano group, a cyano-containing group, an ammonium group, an amide group, a nitro group, a carboxyl group, an ester group, a sulfone group, a sulfonate group, a substituted or unsubstituted C1 to C20 alkyl group, a substituted or unsubstituted C2 to C20 alkenyl group, a substituted or unsubstituted C2 to C20 alkynyl group, or a combination thereof, provided that at least one selected from among L and Z¹ to Z³ includes (e.g., is) a nitro group.

According to one or more embodiments of the present disclosure, a method of forming patterns includes forming an etching-objective layer (e.g., etching-target layer) on a substrate, coating the semiconductor photoresist composition on the etching-objective layer to form a photoresist film, patterning the photoresist film to form a photoresist pattern, and etching the etching-objective layer using the photoresist pattern as an etching mask.

A pattern formed using the semiconductor photoresist composition according to one or more embodiments may implement excellent or suitable resolution by improving CD stability. For example, the composition's tailored chemical structure—particularly the inclusion of nitro-functionalized carboxylic acid compounds and organometallic components—helps reduce variability during the patterning process, thereby enhancing uniformity and fidelity of the resulting features. This contributes to more consistent pattern transfer and better process control.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1A-1E are cross-sectional views for illustrating a method of forming patterns using a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, referring to the drawings, one or more embodiments of the present disclosure will be described in more detail. In the following description of the present disclosure, the well-established functions or constructions will not be described in order to make the present disclosure concise.

To clearly illustrate the present disclosure, certain essential description and relationships are omitted, and throughout the disclosure, the same or similar configuration elements are designated by the same reference numerals. Also, because the size and thickness of each configuration shown in the drawing are shown for better understanding and ease of description, the present disclosure is not necessarily limited thereto.

In the drawings, the thickness of layers, films, panels, regions, and/or the like, may be exaggerated for clarity. In the drawings, the thickness of a part of layers or regions, and/or the like, may be exaggerated for convenience of explanation. It will be understood that if (e.g., when) an element such as a layer, film, region, or substrate is referred to as being “on” another element, it may be directly on the other element or one or more intervening elements may also be present therebetween. In contrast, when an element is referred to as being “directly on” another element, there are no intervening elements present therebetween.

As used herein, “substituted” refers to replacement of a hydrogen by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen by another substituent and remaining of the hydrogen.

As used herein, if (e.g., when) a definition is not otherwise provided, the term “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic saturated hydrocarbon group.

The cycloalkyl group may be a C3 to C8 cycloalkyl group, for example, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, the term “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms).

As used herein, the term “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. When the heteroaryl group is a fused ring, one or more rings thereof may include one to three heteroatoms.

As used herein, unless otherwise defined, the term “alkenyl group” refers to a linear or branched aliphatic hydrocarbon group including at least one double bond as an aliphatic unsaturated alkenyl group.

As used herein, unless otherwise defined, the term “alkynyl group” refers to a linear or branched aliphatic hydrocarbon group including at least one triple bond as an aliphatic unsaturated alkynyl group.

Hereinafter, a semiconductor photoresist composition according to one or more embodiments is described.

A semiconductor photoresist composition according to one or more embodiments may include an organometallic compound; a carboxylic acid compound represented by Chemical Formula 1; and a solvent:

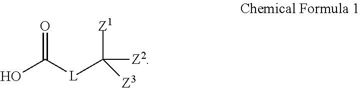

In Chemical Formula 1, L may be a single bond, a substituted or unsubstituted C1 to C10 alkylene group, a substituted or unsubstituted C2 to C10 alkenylene group, or a substituted or unsubstituted C2 to C10 alkynylene group, and Z¹ to Z³ may each independently be hydrogen, a hydroxyl group, a halogen, a cyano group, a cyano-containing group, an ammonium group, an amide group, a nitro group, a carboxyl group, an ester group, a sulfone group, a sulfonate group, a substituted or unsubstituted C1 to C20 alkyl group, a substituted or unsubstituted C2 to C20 alkenyl group, a substituted or unsubstituted C2 to C20 alkynyl group, or a combination thereof, provided that at least one selected from among L and Z¹ to Z³ includes (e.g., is) a nitro group.

A method of forming patterns by using a semiconductor photoresist composition including an organometallic compound includes coating the semiconductor photoresist composition on an etching-objective layer (e.g., etching-target layer), so that the organometallic compound or its cluster molecules in the semiconductor photoresist composition may be coated on the etching-objective layer, and then, proceeding with a first baking process, an exposure process, a second baking process, and a development process to remove an organic material in the photoresist composition and thus to pattern a metal oxide (i.e., etching-objective layer).

Here, the patterning of a metal oxide is affected by various variables such as a temperature, a solvent, a concentration, a catalyst, an atmosphere, and/or the like, and in particular, the smaller pattern size, the relatively larger effect. For example, because a pattern formed by a photoresist composition including an organometallic compound has a very small size in a range of several nanometers (nm) to several tens of nm, the metal oxide-patterning may be more affected by the process conditions than a photoresist.

For example, a concentration of nitrogen oxide (NOₓ) in the atmosphere may affect the pattern formation by a photoresist composition including an organometallic compound. NOₓ is a highly reactive substance that exists in the atmosphere and may react with moisture, sunlight, and/or the like in the atmosphere to cause phenomena such as smog and/or the like. If (e.g., when) the concentration of NOₓ exceeds a set or predetermined level, there may be a problem that a pattern width and/or the like, which are checked after the development, differ from target values.

Accordingly, in the present disclosure, a photoresist composition capable of suppressing or reducing the phenomenon of pattern width deformation due to NOₓ by introducing a compound represented by Chemical Formula 1 and allowing the compound to be coordinated to a central metal of an organometallic compound, thereby reducing a reactivity of the central metal toward radicals, and stabilizing the generated radicals to lower the reactivity, has been developed.

In one or more embodiments, L of Chemical Formula 1 may be, for example, a single bond, a substituted or unsubstituted C1 to C5 alkylene group, a substituted or unsubstituted C2 to C5 alkenylene group, or a substituted or unsubstituted C2 to C5 alkynylene group. In one or more embodiments, L of Chemical Formula 1 may be, for example, a single bond, or a substituted or unsubstituted C1 to C10 alkylene group, or may be, for example, a substituted or unsubstituted C1 to C10 alkylene group, for example an unsubstituted C1 to C5 alkylene group, or for example a C1 to C10 alkylene group substituted with a nitro group.

Z¹ to Z³ of Chemical Formula 1 may each independently be hydrogen, a hydroxyl group, a halogen, a cyano group, a cyano-containing group, an ammonium group, an amide group, a nitro group, a carboxyl group, an ester group, a sulfone group, a sulfonate group, a substituted or unsubstituted C1 to C10 alkyl group, a substituted or unsubstituted C2 to C10 alkenyl group, a substituted or unsubstituted C2 to C10 alkynyl group, or a combination thereof. In one or more embodiments, Z¹ to Z³ of Chemical Formula 1 may be, for example, hydrogen, a cyano group, a cyano-containing group, an ammonium group, an amide group, a nitro group, a carboxyl group, an ester group, a sulfone group, a sulfonate group, or a combination thereof. In one or more embodiments, Z¹ to Z³ of Chemical Formula 1 may be, for example, hydrogen, a cyano group, an ammonium group, an amide group, a nitro group, a carboxyl group, an ester group, or a combination thereof, or, for example, hydrogen, or a nitro group.

In Chemical Formula 1, at least one selected from among L and Z¹ to Z³ includes a nitro group. For example, in one or more embodiments, L may be an alkylene group substituted with a nitro group, an alkenylene group substituted with a nitro group, or alkynylene group substituted with a nitro group, and/or, for example, at least one selected from among Z¹ to Z³ may be a nitro group, an alkyl group substituted with a nitro group, an alkenyl group substituted with a nitro group, or an alkynyl group substituted with a nitro group.

In one or more embodiments, the carboxylic acid compound represented by Chemical Formula 1 may be one selected from among compounds listed in Group 1:

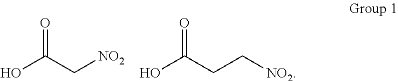 [SMILES: O=C(O)C[N+](=O)[O-] ; O=C(O)CC[N+](=O)[O-]]

The carboxylic acid compound represented by Chemical Formula 1 may be included in an amount of about 0.01 wt % to about 5 wt % based on a total weight of 100 wt % of the semiconductor photoresist composition. In one or more embodiments, the carboxylic acid compound represented by Chemical Formula 1 may be included in an amount of about 0.01 wt % to about 5 wt %, about 0.02 wt % to about 5 wt %, about 0.03 wt % to about 5 wt %, or about 0.05 wt % to about 5 wt % based on the total weight of 100 wt % of the semiconductor photoresist composition. When the carboxylic acid compound represented by Chemical Formula 1 is included in the above amount range, an effect of maintaining pattern formation while suppressing or reducing NOₓ influence may be implemented.

The organometallic compound may be included in an amount of about 0.5 wt % to about 30 wt % based on the total weight of 100 wt % of the semiconductor photoresist composition. In the semiconductor photoresist composition according to one or more embodiments, the organometallic compound may be included in an amount of about 0.5 wt % to about 30 wt %, for example, about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, or for example, about 1 wt % to about 5 wt % based on the total weight of 100 wt % of the semiconductor photoresist composition.

The semiconductor photoresist composition according to one or more embodiments may improve the sensitivity of the photoresist by including the organometallic compound in the above amount range.

The organometallic compound may be an organotin compound including at least one of an organooxy group or an organocarbonyloxy group.

In one or more embodiments, the organometallic compound may be represented by Chemical Formula 2:

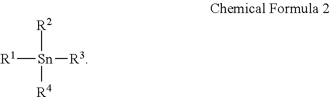

In Chemical Formula 2,
R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{I}, wherein R^{I} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R² to R⁴ is an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f} (COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ) Rⁱ, wherein R^{h}, Rⁱ, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{I}, wherein R^{I} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In one or more embodiments, at least one selected from among R² to R⁴ may be selected from among an alkoxy group and an aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In one or more embodiments, because the organometallic compound represented by Chemical Formula 2 includes —OR^{b} or —OC(═O)R^{c} as a ligand, a pattern formed using a semiconductor photoresist composition including the organometallic compound may exhibit excellent or suitable limit resolution.

Additionally, the ligand of —OR^{b} or —OC(═O)R^{c} may determine the solubility of the organometallic compound represented by Chemical Formula 2 in a solvent.

In one or more embodiments, R¹ may be selected from among a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and a substituted or unsubstituted C7 to C20 arylalkyl group,
R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

In one or more embodiments, R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof,
R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In one or more embodiments, the organometallic compound may be a Sn-containing organometallic compound represented by Chemical Formula 3 or Chemical Formula 4.

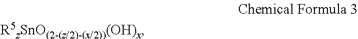

In Chemical Formula 3,
R⁵ may be a C1 to C31 hydrocarbyl group, 0<z≤2, and 0<(z+x)≤4.

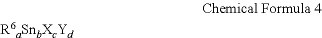

In Chemical Formula 4, R⁶ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X may be sulfur(S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d may each independently be an integer of 1 to 20.

The semiconductor photoresist composition according to one or more embodiments may further include a resin in addition to the aforementioned organometallic compound, carboxylic acid compound represented by Chemical Formula 1, and solvent.

The resin may be a phenol-based resin including at least one aromatic moiety selected from among moieties listed in Group 2.

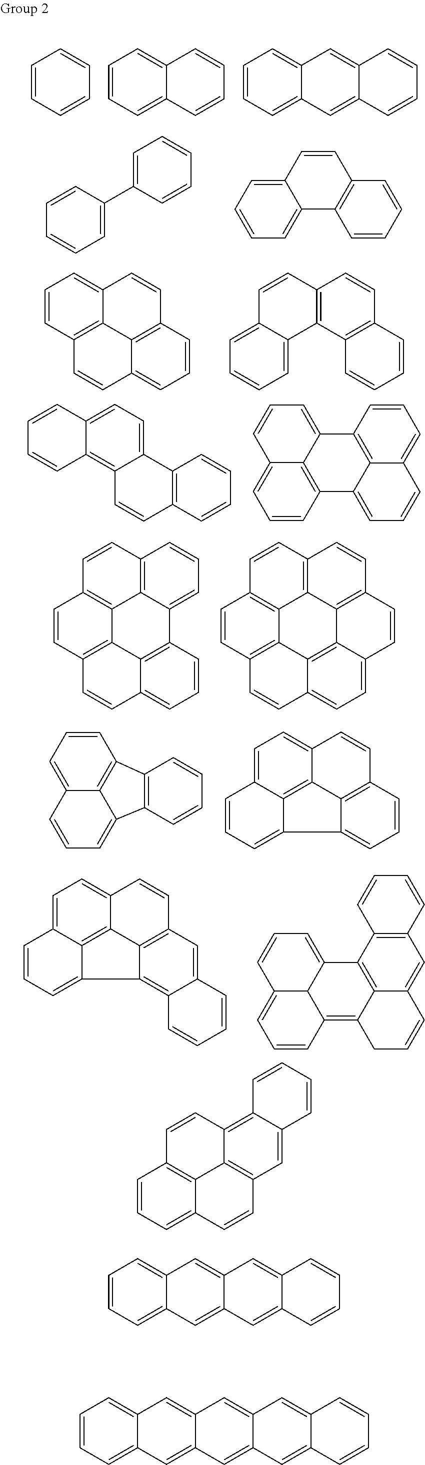

The resin may have a weight average molecular weight of about 500 g/mol to about 20,000 g/mol.

In one or more embodiments, it is desirable that the semiconductor photoresist composition is composed of the aforementioned organometallic compound, carboxylic acid compound represented by Chemical Formula 1, solvent, and resin.

The solvent included in the semiconductor photoresist composition according to one or more embodiments may be an organic solvent, and may be, for example, selected from among aromatic compounds (e.g., xylene, toluene, and/or the like), alcohols (e.g., 4-methyl-2-pentanol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), and/or a mixture thereof, but embodiments of the present disclosure are not limited thereto.

According to one or more embodiments of the present disclosure, the semiconductor photoresist composition may further include one or more additives as needed. Non-limiting examples of the additives may be a surfactant, a crosslinking agent, a leveling agent, an organic acid, a quencher, and/or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. In one or more embodiments, it may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a combination thereof, but embodiments of the present disclosure are not limited thereto.

The quencher may be diphenyl(p-tolyl)amine, methyl diphenyl amine, triphenyl amine, phenylenediamine, naphthylamine, diaminonaphthalene, or a combination thereof.

Amount of each of the additives included in the semiconductor photoresist composition may be controlled or selected depending on desired or suitable properties.

In one or more embodiments, the semiconductor photoresist composition may further include a silane coupling agent as an adherence enhancer in order to improve a close-contacting force with a substrate (e.g., in order to improve adherence of the semiconductor photoresist composition to the substrate). The silane coupling agent may be, for example, a silane compound including a carbon-carbon unsaturated bond such as vinyltrimethoxysilane, vinyl triethoxysilane, vinyl trichlorosilane, vinyl tris(3-methoxyethoxy) silane; 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino) propyl]silane; and/or the like, but embodiments of the present disclosure are not limited thereto.

The semiconductor photoresist composition may be formed into a pattern having a high aspect ratio without a collapse. Accordingly, in order to form a fine pattern having a width (e.g., line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be used to realize extreme ultraviolet lithography using an EUV light source of a wavelength of about 13.5 nm.

According to one or more embodiments, a method of forming patterns using the aforementioned semiconductor photoresist composition is provided. For example, the manufactured pattern may be a photoresist pattern.

The method of forming patterns according to one or more embodiments includes forming an etching-objective layer (e.g., etching-target layer) on a substrate, coating the semiconductor photoresist composition on the etching-objective layer to form a photoresist film, patterning the photoresist film to form a photoresist pattern, and etching the etching-objective layer using the photoresist pattern as an etching mask.

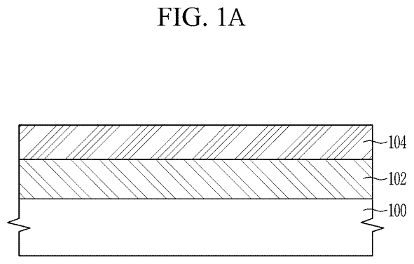

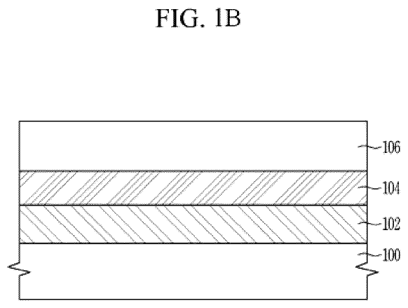

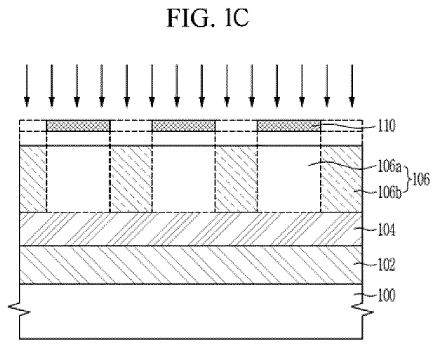

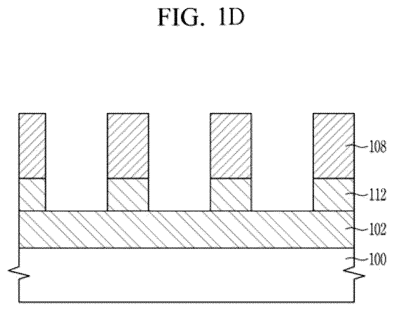

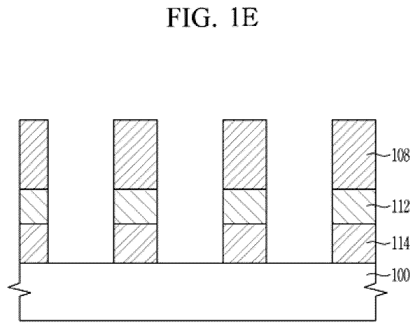

Hereinafter, a method of forming patterns using the semiconductor photoresist composition will be described referring to FIGS. 1A-1E. FIGS. 1A-1E are cross-sectional views for illustrating a method of forming patterns using a semiconductor photoresist composition according to one or more embodiments of the present disclosure.

Referring to FIG. 1A, an object for etching (e.g., etching-objective layer or etching-target layer) is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be, for example, a silicon nitride layer, a polysilicon layer, or a silicon oxide layer.

Subsequently, a resist underlayer composition for forming a resist underlayer 104 is spin-coated on the surface of the washed thin film 102. However, embodiments of the present disclosure are not limited thereto, and various suitable coating methods, for example, a spray coating, a dip coating, a knife edge coating, a printing method (for example, an inkjet printing and a screen printing), and/or the like may be used.

In one or more embodiments, the coating process of the resist underlayer may not be provided. However, hereinafter, a process including a coating of the resist underlayer is described.

Then, the coated resist underlayer composition is dried and baked to form the resist underlayer 104 on the thin film 102. The baking may be performed at about 100° C. to about 500° C., for example, about 100° C. to about 300° C.

The resist underlayer 104 is formed between the substrate 100 and a photoresist film 106 and thus may prevent or reduce non-uniformity of pattern formability of a photoresist line width if (e.g., when) a ray reflected from on the interface between the substrate 100 and the photoresist film 106 or a hardmask between layers is scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

In one or more embodiments, the formation of a pattern by using the semiconductor photoresist composition may include coating the semiconductor photoresist composition on the substrate 100 having the thin film 102 through spin coating, slit coating, inkjet printing, and/or the like and then, drying it to form the photoresist film 106.

The semiconductor photoresist composition has already been illustrated in detail and will not be illustrated again.

Subsequently, the substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as light such as an i-line (a wavelength of about 365 nm), a KrF excimer laser (a wavelength of about 248 nm), an ArF excimer laser (a wavelength of about 193 nm), and/or the like.

In one or more embodiments, light or exposure beam for the exposure may be light in a range of about 5 nm to about 150 nm and/or a high energy wavelength, for example, EUV (extreme ultraviolet; a wavelength of 13.5 nm), and/or may be an E-Beam (an electron beam), and/or the like.

The exposed region 106b of the photoresist film 106 has a different solubility from the unexposed region 106a of the photoresist film 106 by forming a polymer by a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist film 106 becomes indissoluble regarding a developer due to the second baking process.

In FIG. 1D, the unexposed region 106a of the photoresist film is dissolved and removed using the developer to form a photoresist pattern 108. For example, the unexposed region 106a of the photoresist film is dissolved and removed by using an organic solvent such as 2-heptanone and/or the like to complete the photoresist pattern 108 corresponding to a negative tone image.

As described above, the developer used in a method of forming patterns according to one or more embodiments may be an organic solvent. The organic solvent used in the method of forming patterns according to one or more embodiments may be, for example, a ketone such as methylethylketone, acetone, cyclohexanone, 2-heptanone, and/or the like, an alcohol such as 4-methyl-2-propanol, 1-butanol, isopropanol, 1-propanol, methanol, and/or the like, an ester such as propylene glycol monomethyl ether acetate, ethyl acetate, ethyl lactate, n-butyl acetate, butyrolactone, and/or the like, an aromatic compound such as benzene, xylene, toluene, and/or the like, or a combination thereof.

However, the photoresist pattern according to one or more embodiments is not necessarily limited to the negative tone image but may be formed to have a positive tone image. Here, a developer used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like and/or to light such as i-line (a wavelength of about 365 nm), KrF excimer laser (a wavelength of about 248 nm), ArF excimer laser (a wavelength of about 193 nm), and/or the like may provide a photoresist pattern 108 having a width of a thickness of about 5 nm to about 100 nm. For example, in one or more embodiments, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern 108 may have a pitch (center-to-center distance between adjacent features in the pattern) having (with) a half-pitch of less than or equal to about 50 nm, for example less than or equal to about 40 nm, for example less than or equal to about 30 nm, for example less than or equal to about 20 nm, or for example less than or equal to about 15 nm and a line width roughness of less than or equal to about 10 nm, or less than or equal to about 5 nm, less than or equal to about 3 nm, or less than or equal to about 2 nm.

Subsequently, the resist underlayer 104 is etched using the photoresist pattern 108 as an etching mask. Through this etching process, an organic film pattern 112 is formed. The organic film pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be, for example, dry etching using an etching gas, and the etching gas may be, for example, CHF₃, CF₄, Cl₂, BCl₃, or a mixed gas thereof.

In the exposure process, the thin film pattern 114 formed by using the photoresist pattern 108 formed through the exposure process performed by using an EUV light source may have a width corresponding to that of the photoresist pattern 108. For example, in one or more embodiments, the thin film pattern 114 may have a width (e.g., line width) of about 5 nm to about 100 nm which is equal to that of the photoresist pattern 108. For example, in one or more embodiments, the thin film pattern 114 formed by using the photoresist pattern 108 formed through the exposure process performed by using an EUV light source may have a width (e.g., line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, for example, a width (e.g., line width) of less than or equal to about 20 nm, like that of the photoresist pattern 108.

Hereinafter, the present disclosure will be described in more detail through examples of the preparation of the aforementioned semiconductor photoresist composition. However, the present disclosure is technically not restricted by the following examples.

### Synthesis of Organometallic Compounds

### SYNTHESIS EXAMPLE 1

In a 250 mL 2-neck round-bottomed flask, 40.7 g of t-butylSnPhs and 300 g of propionic acid were added and then, heated under reflux for 24 hours. The unreacted propionic acid was removed therefrom under a reduced pressure to obtain a compound represented by Chemical Formula 5.

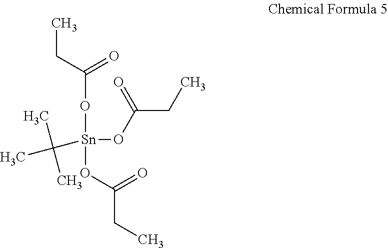 [SMILES: CCC(=O)[O][Sn]([O]C(=O)CC)([O]C(=O)CC)[C](C)(C)C]

### SYNTHESIS EXAMPLE 2

30 mL of anhydrous pentane was added to 10 g of t-AmyISnCl₃, and while maintaining at 0° C., 7.4 g of diethyl amine and 6.1 g of ethanol were added thereto and then, stirred at room temperature for 1 hour. When the reaction was completed, the resultant was filtered, concentrated, and vacuum-dried to obtain a compound represented by Chemical Formula 6.

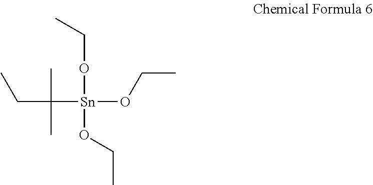

### Preparation of Semiconductor Photoresist Compositions Examples 1 to 9 and Comparative Examples 1 and 2

According to Table, an organometallic selected from among the organometallic compounds represented by Chemical Formula 5 and Chemical Formula 6 obtained in Synthesis Examples 1 and 2 was dissolved in propylene glycol methyl ether acetate (PGMEA) at a concentration of 3%, and a respective carboxylic acid selected from among the carboxylic acid compounds C1 to C3 was added and dissolved at a concentration listed in Table 1, and then filtered through a 0.1 μm PTFE (polytetrafluoroethylene) syringe filter to prepare a respective semiconductor photoresist composition according to Examples and Comparative Examples. Each composition was coated on a silicon wafer to a thickness of 240 Å, and then a respective patterned film was manufactured through PAB (post-apply bake), exposure, PEB (post-exposure back), and development processes.

TABLE 1

| | | Carboxylic acid |
|---|---|---|
| | Organometallic compound | compound |
| | (wt %) | (wt %) |
| Example 1 | Chemical Formula 5 | C1 |
| | (3) | (0.01) |
| Example 2 | Chemical Formula 5 | C1 |
| | (3) | (0.05) |
| Example 3 | Chemical Formula 5 | C1 |
| | (3) | (0.1) |
| Example 4 | Chemical Formula 5 | C2 |
| | (3) | (0.01) |
| Example 5 | Chemical Formula 5 | C2 |
| | (3) | (0.05) |
| Example 6 | Chemical Formula 5 | C2 |
| | (3) | (0.1) |
| Comparative | Chemical Formula 5 | — |
| Example 1 | (3) | |
| Comparative | Chemical Formula 5 | C3 |
| Example 2 | (3) | (0.01) |
| Example 7 | Chemical Formula 6 | C1 |
| | (3) | (0.01) |
| Example 8 | Chemical Formula 6 | C1 |
| | (3) | (0.05) |
| Example 9 | Chemical Formula 6 | C2 |
| | (3) | (0.01) |

C1: Nitroacetic acid
C2: 3-Nitropropionic acid
C3: Propionic acid

### Evaluation 1: Evaluation of Sensitivity and LER Characteristics

Each of the photoresist compositions according to Examples and Comparative Examples was spin-coated for 30 seconds at 1500 rpm on a 200 mm circular silicon wafer whose surface was deposited with hexamethyldisilazane (HMDS), and baked at 110° C. for 60 seconds (After application, it was baked (post-apply bake, PAB)) and then left at room temperature (23±2° C.) for 30 seconds, to prepare a respective coated wafer.

Then, a linear array with a width of 50 nm was projected onto the wafer coated with the photoresist composition using EUV light (Lawrence Berkeley National Laboratory Micro Exposure Tool, MET). Here, pad exposure time was adjusted to ensure that the EUV light in an increased dose was applied to each pad.

Then, the resist and the substrate were baked at 160° C. for 120 seconds on a hot plate after the exposure. The baked film was developed in a PGMEA solvent to form a negative tone image. Finally, the obtained film was baked again at 150° C. for 2 minutes on the hot plate, completing the process.

Critical Dimension Scanning Electron Microscope (CD-SEM) was used to measure resist line widths to exposed dose (energy) changes. The sensitivity to the exposure amount was confirmed from the resist line width values formed differently according to each exposure dose, and the sensitivity and LER were evaluated according to the following criteria, and the results are shown in Table 2.

### Evaluation Criteria for Sensitivity

A: less than 16 mJ/cm²
B: greater than or equal to 16 mJ/cm² and less than 18 mJ/cm²
C: greater than or equal to 18 mJ/cm²
   Evaluation criteria for LER
∘: less than 2 nm
Δ: greater than or equal to 2 nm and less than 5 nm
X: greater than or equal to 5 nm

TABLE 2

| | Sensitivity | LER |
|---|---|---|
| Example 1 | A | ◯ |
| Example 2 | B | ◯ |
| Example 3 | A | ◯ |
| Example 4 | B | ◯ |
| Example 5 | A | ◯ |
| Example 6 | A | ◯ |
| Example 7 | A | ◯ |
| Example 8 | A | ◯ |
| Example 9 | A | Δ |
| Comparative | C | X |
| Example 1 | | |
| Comparative | B | Δ |
| Example 2 | | |

From the results in Table 2, the pattern formed using each of the semiconductor photoresist compositions according to Examples 1 to 9 exhibited superior sensitivity and smaller LER compared to Comparative Examples 1 and 2.

### Evaluation 2: Evaluation of Coating Characteristics

Each of the semiconductor photoresist compositions according to Examples and Comparative Examples was spin-coated on a wafer at 1500 rpm for 60 seconds and baked at 110° C. for 60 seconds to form a respective thin film, which was taken an image of with an atomic force microscopy (AFM) and/or the like, and the image was used to measure surface roughness of the thin film according to the following reference by using a software (ex. Optical Profiler), and the results are shown in Table 3.

Among the surface roughness, root mean square roughness (R_{q}) refers to root square mean (rms) of vertical values in the root profile within reference lengths.

### Evaluation Criteria

∘: R_{q} is less than or equal to 0.4 nm
X: R_{q} is greater than 0.4 nm

TABLE 3

| | Surface roughness |
|---|---|
| Example 1 | ◯ |
| Example 2 | ◯ |
| Example 3 | ◯ |
| Example 4 | ◯ |
| Example 5 | ◯ |
| Example 6 | ◯ |
| Example 7 | ◯ |
| Example 8 | ◯ |
| Example 9 | ◯ |
| Comparative | X |
| Example 1 | |
| Comparative | ◯ |
| Example 2 | |

From the results in Table 3, the pattern formed using each of the semiconductor photoresist compositions according to Examples 1 to 9 exhibited smaller surface roughness than Comparative Example 1, i.e., better coating properties.

### Evaluation 3: Evaluation of CD Uniformity

Each of the semiconductor photoresist compositions according to Examples 1 to 9 and Comparative Examples 1 and 2 was spin-coated on a 200 mm circular silicon wafer at 1500 rpm for 30 seconds and then, heated at 110° C. for 60 seconds to prepare a respective thin film.

Subsequently, a linear array with a line width of 180 nm was projected onto the wafer coated with the photoresist composition for a photoresist by using KrF light. Then, the resist and the substrate were heated at 180° C. on a hot plate for 120 seconds. The baked film was developed with a PGMEA solvent to form a negative tone image. Finally, baking at 200° C. for 180 seconds was performed to complete the process.

The resists were measured with respect to CD values when there was no NOₓ in the atmosphere and when NOₓ was at a concentration of 0.01 ppm or more by using CD-SEM, which were used to calculate a CD change (ΔCD(%)), and the results are shown in Table 4. The NOₓ concentration was measured by using a Sky2000-NOₓ detector (Safegas). The CD change was calculated according to the following equation.

$$Δ CD ( \% ) = \{ ( {CD}_{\geq 0.01 ppm NOx} / {CD}_{w / o NOx} ) \times 100 \} \qquad Equation$$

TABLE 4

| | ΔCD(%) |
|---|---|
| Example 1 | 47.52 |
| Example 2 | 43.48 |
| Example 3 | 44.05 |
| Example 4 | 6.32 |
| Example 5 | 1.18 |
| Example 6 | 2.67 |
| Example 7 | 101.33 |
| Example 8 | 97.06 |
| Example 9 | 96.61 |
| Comparative Example 1 | 89.00 |
| Comparative Example 2 | 131.65 |

From the results in Table 4, the patterns formed using each of the semiconductor photoresist compositions according to Examples 1 to 6 exhibited a smaller CD change according to the change in NOₓ concentration compared to Comparative Examples 1 and 2, i.e., excellent or suitable resistance to the influence of NOₓ.

As utilized herein, the terms “and/or” and “or” may include any and all combinations of one or more of the associated listed items. The “/” utilized below may be interpreted as “and” or as “or” depending on the situation. In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

It will be further understood that the terms “comprise(s)/comprising”, “include(s)/including,” or “have/has/having,” when utilized in the present disclosure, specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A pattern forming device, a semiconductor forming device and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, certain embodiments of the present disclosure have been described and illustrated, however, it is apparent to a person with ordinary skill in the art that the present disclosure is not limited to the presented embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure. It is further to be understood that the scope of the present disclosure is defined by the appended claims and equivalents thereof rather than the detailed description described above, and all modifications and alterations derived from the claims and their equivalents fall within the scope of the present disclosure.

### REFERENCE NUMERALS

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising
an organometallic compound;
a carboxylic acid compound represented by Chemical Formula 1; and
a solvent: 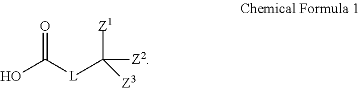
wherein, in Chemical Formula 1,
L is a single bond, a substituted or unsubstituted C1 to C10 alkylene group, a substituted or unsubstituted C2 to C10 alkenylene group, or a substituted or unsubstituted C2 to C10 alkynylene group, and
Z¹ to Z³ are each independently hydrogen, a hydroxy group, a halogen, a cyano group, a cyano-containing group, an ammonium group, an amide group, a nitro group, a carboxyl group, an ester group, a sulfone group, a sulfonate group, a substituted or unsubstituted C1 to C20 alkyl group, a substituted or unsubstituted C2 to C20 alkenyl group, a substituted or unsubstituted C2 to C20 alkynyl group, or a combination thereof,
provided that at least one selected from among L and Z¹ to Z³ comprises a nitro group.

2. The semiconductor photoresist composition as claimed in claim 1, wherein L is a single bond or a substituted or unsubstituted C1 to C10 alkylene group.

3. The semiconductor photoresist composition as claimed in claim 1, wherein Z¹ to Z³ are each independently hydrogen, a cyano group, an ammonium group, an amide group, a nitro group, a carboxyl group, an ester group, or a combination thereof, provided that at least one selected from among Z¹ to Z³ is a nitro group.

4. The semiconductor photoresist composition as claimed in claim 1, wherein the carboxylic acid compound represented by Chemical Formula 1 is in an amount of 0.01 wt % to 5 wt % based on a total weight of 100 wt % of the semiconductor photoresist composition.

5. The semiconductor photoresist composition as claimed in claim 1, wherein the carboxylic acid compound represented by Chemical Formula 1 is selected from among compounds listed in Group 1:

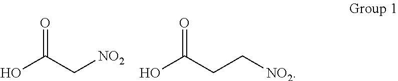 [SMILES: O=C(O)C[N+](=O)[O-] ; O=C(O)CC[N+](=O)[O-]]

6. The semiconductor photoresist composition as claimed in claim 1, wherein the semiconductor photoresist composition further comprises one or more additives selected from among a surfactant, a crosslinking agent, a leveling agent, an organic acid, a quencher, and a combination thereof.

7. The semiconductor photoresist composition as claimed in claim 1, wherein the organometallic compound comprises an organotin compound comprising at least one of an organooxy group or an organocarbonyloxy group.

8. The semiconductor photoresist composition as claimed in claim 1, wherein the organometallic compound is represented by Chemical Formula 2: 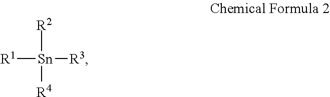
and
wherein, in Chemical Formula 2,
R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{I}, wherein R^{I} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R² to R⁴ is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f} (COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{I}, wherein R^{I} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

9. The semiconductor photoresist composition as claimed in claim 8, wherein at least one selected from among R² to R⁴ is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

10. The semiconductor photoresist composition as claimed in claim 9, wherein R¹ is selected from among a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and a substituted or unsubstituted C7 to C20 arylalkyl group,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is a hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or combination thereof.

11. The semiconductor photoresist composition as claimed in claim 1, wherein the organometallic compound is represented by Chemical Formula 3 or Chemical Formula 4: 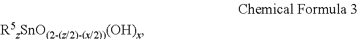
in Chemical Formula 3,
R⁵ being a C1 to C31 hydrocarbyl group, 0<z≤2, and 0< (z+x)≤4; and 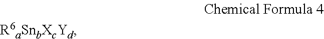
in Chemical Formula 4,
R⁶ being a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, ethylene oxide group, propylene oxide group, or a combination thereof,
X being sulfur, selenium, or tellurium,
Y being —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d being each independently an integer of 1 to 20.

12. A method, comprising
forming an etching-objective layer on a substrate;
coating the semiconductor photoresist composition of claim 1 on the etching-objective layer to form a photoresist film;
patterning the photoresist film to form a photoresist pattern; and
etching the etching-objective layer utilizing the photoresist pattern as an etching mask,
wherein the method is a method of forming patterns.

13. A system, comprising
means for forming an etching-objective layer on a substrate;
means for coating the semiconductor photoresist composition of claim 1 on the etching-objective layer to form a photoresist film;
means for patterning the photoresist film to form a photoresist pattern; and
means for etching the etching-objective layer utilizing the photoresist pattern as an etching mask,
wherein the system is a system of forming patterns.
